(19) United States
(12) Patent Application Publication
(10) Pub. No.: US 2026/0324249 A1
(43) Pub. Date: Oct. 15, 2026

(54) DISPLAY PANEL, MANUFACTURING METHOD THEREOF AND DISPLAY DEVICE

(71) Applicant: HKC CORPORATION LIMITED, Shenzhen (CN)

(72) Inventors: ZHISHENG XIE, Shenzhen (CN); Yangling TANG, Shenzhen (CN); Qin LIANG, Shenzhen (CN); Xiufeng ZHOU, Shenzhen (CN); Haijiang YUAN, Shenzhen (CN)

(21) Appl. No.: 19/461,778

(22) Filed: Jan. 28, 2026

(30) Foreign Application Priority Data
Feb. 10, 2025 (CN) 202510146656.2

(51) Int. Cl. H10K 59/80; H10K 59/12; H10K 59/122; H10K 71/60; H10K 102/00

(52) U.S. Cl. CPC H10K 59/80516; H10K 59/1201; H10K 59/122; H10K 59/80517; H10K 59/80518; H10K 71/60; H10K 2102/351

(57) ABSTRACT

Disclosed are a display panel, a manufacturing method thereof and a display device. The display panel includes a substrate, a pixel-defining layer and a plurality of light-emitting elements. Each of the plurality of light-emitting elements includes an anode, a light-emitting functional layer and a cathode. Each of the plurality of light-emitting elements further includes an anode auxiliary electrode, the anode auxiliary electrode is disposed between the anode and the light-emitting functional layer, the anode auxiliary electrode is formed of one or more of metal, metal alloy, or metal oxide. The display panel further includes a plurality of partition structures, each of the plurality of partition structures is configured to separate the anode auxiliary electrodes of two adjacent light-emitting elements when depositing an entire surface of the anode auxiliary electrodes.

### CROSS-REFERENCE TO RELATED APPLICATIONS

The present disclosure claims the priority and benefit of Chinese patent disclosure number 2025101466562, titled "Display Panel, Manufacturing Method Thereof and Display Device" and filed on Feb. 10, 2025 with China National Intellectual Property Administration, the entire contents of which are incorporated herein by reference.

### TECHNICAL FIELD

The present disclosure relates to the technical field of display, and more particularly relates to a display panel, a manufacturing method thereof and a display device.

### BACKGROUND

The description provided in this section is intended for the mere purpose of providing background information related to the present disclosure but does not necessarily constitute prior art.

Organic Light-Emitting Diode (hereinafter referred to as OLED) display device is widely used in various fields due to their light weight, wide viewing angle, fast response, low temperature resistance, high luminous efficiency, and the ability to produce curved flexible displays. As mass production technology becomes increasingly mature, OLED display panel is gradually becoming mainstream real-world panels.

However, due to process reasons, when etching the anode of a light-emitting element of the OLED display panel, the protective layer may not be removed cleanly, resulting in residues. The above problem may lead to an increase in the contact resistance between the anode and the organic material in the light-emitting functional layer, thereby causing the driving voltage of the light-emitting element to increase or the lifespan of the light-emitting element to reduce rapidly.

### SUMMARY

The purpose of the present disclosure is to provide a display panel, a manufacturing method thereof and a display device, which improve the film interface between the anode and the light-emitting functional layer by adding an anode auxiliary electrode between the anode and the light-emitting functional layer, thereby improving the luminous efficiency and life of the plurality of light-emitting elements.

The present disclosure discloses a display panel, including a substrate, a pixel-defining layer and a plurality of light-emitting elements. The pixel-defining layer is disposed on the substrate and provided with a plurality of opening areas. The plurality of light-emitting elements are arranged in an array on the substrate and respectively located in the plurality of opening areas. Each of the plurality of light-emitting elements includes an anode, a light-emitting functional layer and a cathode, the anode is disposed on the substrate, the light-emitting functional layer is disposed on the anode, and the cathode is disposed on the light-emitting functional layer. Each of the plurality of light-emitting elements further includes an anode auxiliary electrode, the anode auxiliary electrode is disposed between the anode and the light-emitting functional layer, the anode auxiliary electrode is formed of one or more of metal, metal alloy, or metal oxide. The display panel further includes a plurality of partition structures, each of the plurality of partition structures is configured to separate the anode auxiliary electrodes of two adjacent light-emitting elements when depositing an entire surface of the anode auxiliary electrodes.

The present disclosure discloses a method for manufacturing a display panel, including:
providing a substrate; forming an anode by depositing and patterning on the substrate;
forming a pixel-defining layer by depositing and patterning, and
forming a plurality of opening areas;
forming a plurality of partition structures; forming an anode auxiliary electrode in each of the plurality of opening areas through the plurality of partition structures when depositing an entire surface of an anode auxiliary electrode material;
forming a light-emitting functional layer and a cathode to form a plurality of light-emitting elements in the plurality of opening areas; and
forming a display panel.

The present disclosure further discloses a display device, including a display panel and a driving circuit configured to drive the display panel. The display panel includes a substrate, a pixel-defining layer and a plurality of light-emitting elements. The pixel-defining layer is disposed on the substrate and provided with a plurality of opening areas. The plurality of light-emitting elements are arranged in an array on the substrate and respectively located in the plurality of opening areas. Each of the plurality of light-emitting elements includes an anode, a light-emitting functional layer and a cathode, the anode is disposed on the substrate, the light-emitting functional layer is disposed on the anode, and the cathode is disposed on the light-emitting functional layer. Each of the plurality of light-emitting elements further includes an anode auxiliary electrode, the anode auxiliary electrode is disposed between the anode and the light-emitting functional layer, the anode auxiliary electrode is formed of one or more of metal, metal alloy, or metal oxide. The display panel further includes a plurality of partition structures, each of the plurality of partition structures is configured to separate the anode auxiliary electrodes of two adjacent light-emitting elements when depositing an entire surface of the anode auxiliary electrodes.

In the present disclosure, an anode auxiliary electrode is added to the anode and the light-emitting functional layer. During the deposition process, the anode auxiliary electrode has a good contact interface with the anode. Although reside issues may exist on the anode, the problem of increased contact resistance does not arise since the anode auxiliary electrode also has conductive properties and is in full contact with the anode. The advantage of the anode auxiliary electrode is that the anode auxiliary electrode may be isolated by the plurality of partition structures without etching, allowing the anode auxiliary electrode of each of the plurality of light-emitting elements to be independently arranged, thereby avoiding a series of problems caused by etching to the anode auxiliary electrode, such as etching residue and etching oxidation. Importantly, the plurality of partition structures are configured to process the anode auxiliary electrode and the subsequent light-emitting functional layer under the same ambient condition. After the anode auxiliary electrode is formed, no etching process is required, and the light-emitting functional layer is directly deposited, thereby avoiding the influence of the intermediate process on the film interface between the anode auxiliary electrode and the light-emitting functional layer. Moreover, the anode auxiliary electrode and the light-emitting functional layer are formed in sequence under the same ambient condition, such as a vacuum ambient condition, so that a contact interface between the materials of the anode auxiliary electrode and the light-emitting functional layer is formed, thereby improving the light-emitting efficiency and service life of the plurality of light-emitting elements.

### BRIEF DESCRIPTION OF DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of a display panel of a first embodiment of the present disclosure.

FIG. 2 is a schematic diagram of a partition structure of a first embodiment of the present disclosure.

FIG. 3 is a schematic diagram of an anode of a first embodiment of the present disclosure.

FIG. 4 is a schematic diagram of a light-emitting element of a first embodiment of the present disclosure.

FIG. 5 is a schematic diagram of steps of a method for manufacturing a display panel according to the first embodiment of the present disclosure.

FIG. 6 is a schematic diagram of steps of another method for manufacturing a display panel according to the first embodiment of the present disclosure.

FIG. 7 is a schematic diagram of manufacturing a display panel according to a first embodiment of the present disclosure.

FIG. 8 is a schematic diagram of a display panel of a second embodiment of the present disclosure.

FIG. 9 is a schematic diagram of a display device according to the present disclosure.

### REFERENCE NUMERALS

100, display panel; 101, opening area; 102, non-opening area; 110, substrate; 120, pixel-defining layer; 121, partition groove; 130, light-emitting element; 131, anode; 1311, first transparent electrode layer; 1312, first reflective electrode layer; 1313, second transparent electrode layer; 1314, first electrode layer; 132, light-emitting functional layer; 1321, hole-injection layer; 1322, hole-transport layer; 1323, an electron-blocking layer; 1324, light-emitting layer; 1325, hole-blocking layer; 1326, electron-transport layer; 1327, electron-injection layer; 133, cathode; 134, anode auxiliary electrode; 1341, first auxiliary electrode layer; 1342, second reflective electrode layer; 1343, second auxiliary electrode layer; 140, partition layer; 141, partition structure; 150, pixel driving layer; 200, display device; 210, driving circuit.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. Additionally, directional or positional terms such as "upper," "lower," "left," "right," "vertical," or "horizontal" are described based on orientations or relative positional relationships shown in the accompanying drawings, which are used for simplified description to facilitate understanding of the present application and do not imply that the devices or elements described should have specific orientations or be constructed or operated in specific orientations. These terms should not be construed as limiting the present disclosure. For those skilled in the art, the specific meaning of the above terms in the context of the present disclosure may be understood according to the specific situation.

The present disclosure is described below in detail with reference to the accompanying drawings and optional embodiments.

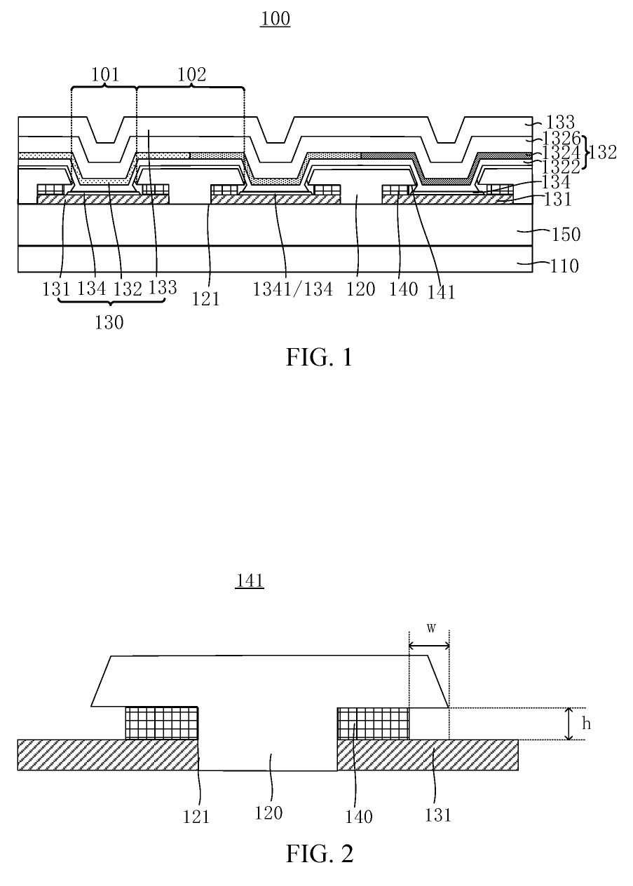

FIG. 1 is a schematic diagram of a display panel of a first embodiment of the present disclosure. As shown in FIG. 1, the present disclosure discloses a display panel. The display panel 100 includes a substrate 110, a pixel-defining layer 120, a plurality of light-emitting elements 130 and a plurality of partition structures 141. The pixel-defining layer 120 is disposed on the substrate 110 and the pixel-defining layer 120 is provided with a plurality of opening areas 101. The plurality of light-emitting elements 130 are arranged in an array on the substrate 110 and respectively located in the plurality of opening areas 101. Each of the plurality of light-emitting elements 130 includes an anode 131, a light-emitting functional layer 132 and a cathode 133, the anode 131 is disposed on the substrate 110, the light-emitting functional layer 132 is disposed on the anode 131, and the cathode 133 is disposed on the light-emitting functional layer 132. Each of the plurality of light-emitting elements 130 further includes an anode auxiliary electrode 134, the anode auxiliary electrode 134 is disposed between the anode 131 and the light-emitting functional layer 132, the anode auxiliary electrode 134 is formed of one or more of metal, metal alloy, or metal oxide. Each of the plurality of partition structures is configured to separate the anode auxiliary electrodes of two adjacent light-emitting elements when depositing an entire surface of the anode auxiliary electrodes.

In the present disclosure, an anode auxiliary electrode 134 is added to the anode 131 and the light-emitting functional layer 132. During the deposition process, the anode auxiliary electrode 134 has a good contact interface with the anode 131. Although residue issues may exist on the anode 131, the problem of increased contact resistance does not arise since the anode auxiliary electrode 134 also has conductive properties and is in full contact with the anode 131. The advantage of the anode auxiliary electrode 134 is that the anode auxiliary electrode 134 may be isolated by the plurality of partition structures 141 without etching, allowing the anode auxiliary electrode 134 of each of the plurality of light-emitting elements 130 to be independently arranged, thereby avoiding a series of problems caused by etching to the anode auxiliary electrode 134, such as etching residue and etching oxidation. Importantly, the plurality of partition structures 141 are configured to process the anode auxiliary electrode 134 and the subsequent light-emitting functional layer 132 under the same ambient condition. After the anode auxiliary electrode 134 is formed, no etching process is required, and the light-emitting functional layer 132 is directly deposited, thereby avoiding the influence of the intermediate process on the film interface between the anode auxiliary electrode 134 and the light-emitting functional layer 132. Moreover, the anode auxiliary electrode 134 and the light-emitting functional layer 132 are formed in sequence in the same ambient condition, such as a vacuum ambient condition, so that a contact interface between the materials of the anode auxiliary electrode 134 and the light-emitting functional layer 132 is formed, thereby improving the light-emitting efficiency and service life of the plurality of light-emitting elements 130.

It is worth mentioning that in the process of manufacturing the plurality of light-emitting elements 130 of the display panel 100, the anode 131 is generally formed first, and the pixel-defining layer 120 is formed on the anode 131. After patterning the pixel-defining layer 120, the required pixel area, i.e., the plurality of opening areas 101, is etched out. The plurality of opening areas 101 are configured to form a light-emitting functional layer 132 and a cathode 133, etc. After the anode 131 is deposited, it needs to undergo a patterning process and a subsequent patterning process of the pixel-defining layer 120 before the light-emitting functional layer 132 is formed. The patterning process generally employs photolithography. After a portion of the anode 131 not to be etched is protected by a photoresist, the unwanted portion of the anode 131 material is etched, and the photoresist on the anode 131 is removed after the etching is completed. In this process, on the one hand, there is a situation where the above-mentioned photoresist is not removed cleanly, resulting in residual photoresist on the anode 131 causing abnormalities. On the other hand, since the etching process is generally completed in an atmospheric environment, a surface of the anode 131 is prone to oxidation during the etching process. In particular, during the oxidation process, an uneven surface of the anode 131 with peaks or pinholes is more prone to oxidation, thereby increasing the contact resistance between the anode 131 and the light-emitting functional layer 132. Generally speaking, in response to the above problem, an additional plasma treatment may be added during the evaporation of the light-emitting functional layer 132 to clean the surface of the anode 131. However, it is difficult to control the process conditions of the plasma treatment. If the plasma treatment is too heavy, it is easy to damage the anode 131, and if the plasma treatment is too light, it is easy to cause the problem of incomplete cleaning, thereby failing to achieve the effect of cleaning the surface of the anode 131. However, in the technical solution of the present disclosure, by setting an anode auxiliary electrode 134 between the anode 131 and the light-emitting functional layer 132, the above problem is solved by the anode auxiliary electrode 134, thereby improving the display effect and service life of the display panel 100.

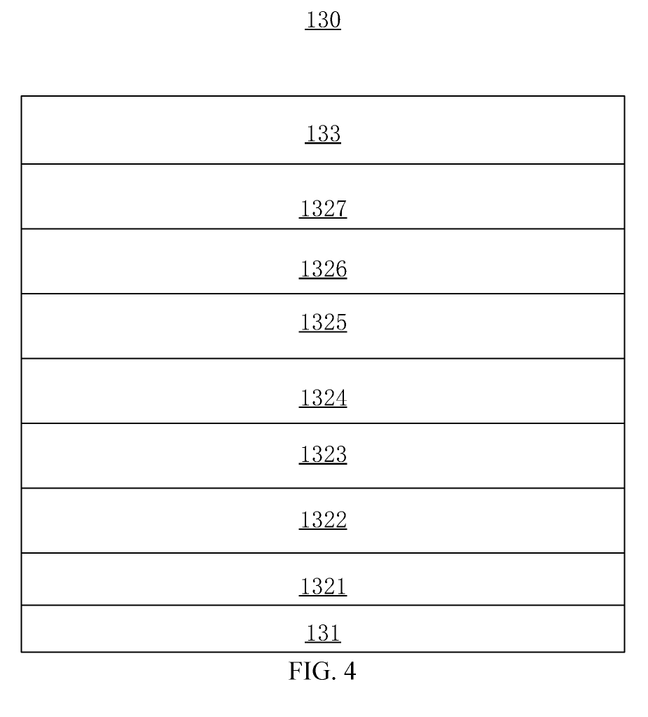

FIG. 2 is a schematic diagram of a partition structure of a first embodiment of the present disclosure. As shown in FIG. 2, the display panel 100 further includes a partition layer 140, the partition layer 140 is disposed below the pixel-defining layer 120 and disposed on the anode 131, and the partition layer is in direct contact with the anode 131. In an orthographic projection on the substrate 110, a projection boundary of the partition layer 140 is within a projection range of the pixel-defining layer 120, a preset distance w as shown in FIG. 4 is provided between an outermost projection boundary of the partition layer 140 and an outermost projection boundary of the pixel-defining layer 140, each of the plurality of partition structures 141 is formed by the pixel-defining layer 120 and the partition layer 140.

In some embodiments, the partition layer 140 is added between the pixel-defining layer 120 and the anode 131, so that the partition layer 140 is at the bottom and has a width less than a width of the pixel-defining layer 120, and the edge of the pixel-defining layer 120 protrudes from the partition layer 140, thereby forming the plurality of partition structures 141. The plurality of partition structures 141 are respectively looped the plurality of opening areas 101, and when the anode auxiliary electrode 134 is evaporated, the redundant anode auxiliary electrode material on the pixel-defining layer 120 is disconnected from the anode 131, so that the anode auxiliary electrode 134 is independently arranged.

In the process of forming the plurality of partition structures 141, the material of the partition layer 140 may be metal material or metal alloy material, but it is different from the material utilized for the anode 131. The main consideration is that in the process of etching the partition layer 140 to form the pixel-defining layer 120, a wet etching process is generally required. The partition layer 140 is side-etched, since the wet etching process is isotropic, so that the edge of the pixel-defining layer 120 protrudes from the partition layer 140, thereby forming the plurality of partition structures 141. In the etching process, if the anode 131 and the partition layer 140 are made of the same material, the anode 131 is also etched accordingly, causing the anode 131 to be etched and damaged. The etching solution only reacts with the material of the partition layer 140, but not with the material of the anode 131, therefore, the anode 131 remains unaffected, when the anode 131 and the partition layer 140 are made of different materials, since the etching solution only etches the corresponding material, that is, during the etching process.

The partition layer 140 employed in the present disclosure, apart from forming the plurality of partition structures 141, also protects the anode 131 during the etching process.

In the process of forming the anode 131, it is necessary to form independently arranged anodes 131 in the plurality of opening areas 101. In some embodiments, the anode 131 and the partition layer 140 disposed on the anode 131 are etched at the same time, and the partition layer 140 is configured to protect the anode 131. That is, in the process of etching the anode 131, it is not necessary to utilize a photoresist to directly contact the anode 131, but the photoresist is disposed on the partition layer 140. As a result, the partition layer 140 and the anode 131 are etched simultaneously, forming the partition groove 121 in the non-opening area 102, thus enabling the independent disposition of the plurality of anodes 131. The pixel-defining layer 120 is configured to insulate the location of the partition groove 121, and the pixel-defining layer 120 partially overlaps with the anode 131 and the partition layer 140. The pixel-defining layer 120 is disposed to define the plurality of opening areas 101, that is, the areas where the plurality of light-emitting elements 130 are disposed.

In this embodiment, the partition layer 140 is provided by covering the anode 131. In the process of etching the anode 131, no photoresist is provided on the anode 131, that is, the anode 131 is not in contact with the photoresist, thereby avoiding the problem of residual photoresist material on the anode 131 caused by unclean film stripping. Moreover, the partition layer 140 is etched again in the subsequent process of forming the plurality of partition structures 141, thereby exposing the anode 131 from the plurality of opening areas 101, so that the anode 131 may directly contact the subsequent anode auxiliary electrode 134 in the plurality of opening areas 101. In the process of forming the plurality of partition structures 141 by providing the partition layer 140, the problem of residual photoresist in the etching process of the anode 131 is also improved. In addition, with the addition of the partition layer 140 to form the plurality of partition structures 141, although etching technology is employed, neither the etching of the partition layer 140 nor the etching of the plurality of partition structures 141 requires additional photo-masks, and both may be directly completed using existing process equipment, which is suitable for production on current production lines.

Each of the plurality of light-emitting elements 130 in the display panel 100 may generally be controlled individually, specifically by connecting the anodes 131 of the plurality of light-emitting elements 130 to a thin film transistor respectively, and driving them through a pixel driving circuit. The plurality of light-emitting elements 130 are controlled to have different luminous brightness, when the pixel driving circuit assigns different voltages to the anodes 131. The pixel driving circuit of the display panel 100 is formed by thin film technology, and may also be called a pixel driving layer 150, which is generally arranged on the substrate 110 and under the anodes 131. The pixel driving layer 150 is generally formed of multiple metal layers and insulating layers to form thin film transistors, driving circuits, etc., so as to achieve control of the plurality of light-emitting elements 130.

Specifically, since each of the anodes 131 of the plurality of light-emitting elements 130 need to be connected to the corresponding thin film transistors, generally speaking, they are connected through a via hole, and an extension line of the anode 131 is connected to the thin film transistor through the via hole. In some embodiments, the positions of the via hole may be set corresponding to the positions of the partition layer 140. That is, on the orthographic projection of the substrate 110, the projection of the via hole between the anodes 131 of the plurality of light-emitting elements 130 and the thin film transistors overlaps with the projection of the partition layer 140. The resistance at the via hole is reduced through the conductive effect of the partition layer 140.

In some embodiments, the anode includes a first transparent electrode layer, a first reflective electrode layer, and a second transparent electrode layer, the first reflective electrode layer is disposed between the first transparent electrode layer and the second transparent electrode layer; the first reflective electrode layer is formed of reflective metal material.

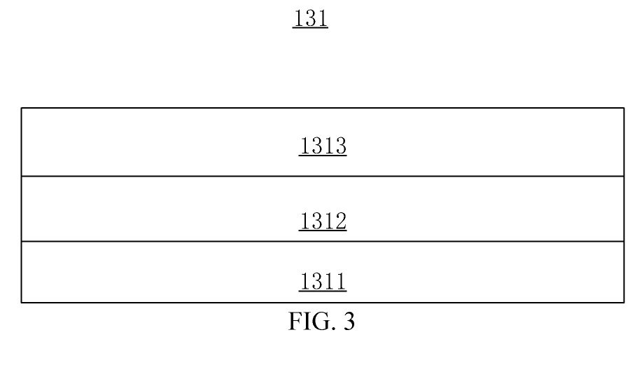

FIG. 3 is a schematic diagram of an anode of a first embodiment of the present disclosure. As shown in FIG. 3, in the current display panel 100 mainly using organic light-emitting materials, the anode 131 is generally disposed in a sandwich configuration. That is, the first reflective electrode layer 1312 is sandwiched between the first transparent electrode layer 1311 and the second transparent electrode layer 1313. On the one hand, the first reflective electrode layer 1312 is protected. On the other hand, since the first transparent electrode layer 1311 is generally formed of metal oxides such as indium tin oxide (hereinafter referred to as ITO), the indium tin oxide has a higher work function, so that the plurality of light-emitting elements 130 generate more holes on the side of the anode 131, thereby improving the luminous efficiency of the plurality of light-emitting elements 130. In some embodiments, the anode 131 is a three-layer electrode layer of ITO, silver (Ag), and ITO. The material of the partition layer 140 may be a metal oxide such as indium zinc oxide (hereinafter referred to as IZO), metals such as aluminum (Al), molybdenum (Mo), copper (Cu), or an alloy of the above metals and other metals.

Specifically, the anode auxiliary electrode 134 includes a first auxiliary electrode layer 1341, which is disposed on the second transparent electrode layer 1313 and in direct contact with the second transparent electrode layer 1313. The first auxiliary electrode layer 1341 of the present embodiment may be selected as metal oxide material with a high work function such as ITO, IZO, etc., or may also be selected as metal or metal alloy material with a high work function such as Pt, Ni, Au, etc. However, considering that the metal or metal alloy material has the characteristic of being opaque when the thickness thereof is thick, it is necessary to limit the thickness of the metal or metal alloy material, that is, the thickness of the first auxiliary electrode layer 1341 should not exceed 30 nm (300 angstroms). Of course, the thickness of the first auxiliary electrode layer 1341 may not be too thin, and at least needs to be greater than or equal to 10 angstroms.

FIG. 4 is a schematic diagram of a light-emitting element of a first embodiment of the present disclosure. As shown in FIG. 4, the light-emitting functional layer 132, from the anode 131 to the cathode 133, respectively includes multiple film-layer structures such as a hole-injection layer 1321, a hole-transport layer 1322, an electron-blocking layer 1323, a light-emitting layer 1324, a hole-blocking layer 1325, an electron-transport layer 1326, and an electron-injection layer 1327. The electron-injection layer 1327 is disposed on the side of the cathode 133, and the hole-injection layer 1321 is disposed on the side of the anode 131.

Specifically, considering that the plurality of partition structures 141 at least need to partition the anode auxiliary electrode 134 and the light-emitting functional layer 132, it is necessary to define the partitioning ability of the plurality of partition structures 141. Since the partitioning ability of the plurality of partition structures 141 is mainly related to the preset distance and the thickness of the partition layer 140, it is necessary to define the preset distance and the thickness of the partition layer 140 in the plurality of partition structures 141. The preset distance w is greater than or equal to 5,000 angstroms and less than or equal to 50,000 angstroms, and the thickness h of the partition layer 140 is greater than or equal to 100 angstroms and less than or equal to 10,000 angstroms. Of course, if the thickness of the partition layer 140 is considered in the plurality of partition structures 141 in some embodiments, the plurality of partition structures 141 may only be utilized to partition the anode auxiliary electrode 134, and the subsequent light-emitting functional layer 132 may be formed through the employment of a metal mask evaporation technology. Of course, in the above another embodiment where the plurality of partition structures 141 are partition structures, the light-emitting functional layer 132 may also be formed by using the partition structure through mask-less evaporation technology.

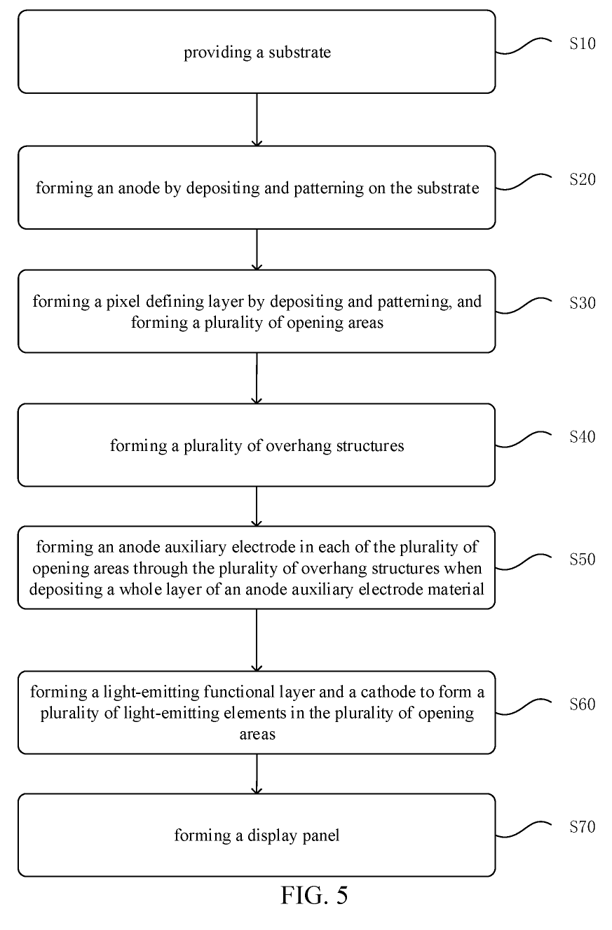

FIG. 5 is a schematic diagram of steps of a method for manufacturing a display panel according to the first embodiment of the present disclosure. As shown in FIG. 5, the present disclosure discloses a method for manufacturing a display panel corresponding to the above-mentioned display panel. The method for manufacturing a display panel includes:

S10: providing a substrate;

S20: forming an anode by depositing and patterning on the substrate;

S30: forming a pixel-defining layer by depositing and patterning, and forming a plurality of opening areas;

S40: forming a plurality of partition structures;

S50: forming an anode auxiliary electrode in each of the plurality of opening areas through the plurality of partition structures when depositing an entire surface of an anode auxiliary electrode material;

S60: forming a light-emitting functional layer and a cathode to form a plurality of light-emitting elements in the plurality of opening areas; and

S70: forming a display panel.

In some embodiments, the present disclosure adds an anode auxiliary electrode 134 on the anode 131 and the light-emitting functional layer 132, and separates the anode auxiliary electrode 134 through the plurality of partition structures 141, so that the anode auxiliary electrodes 134 of each of the plurality of light-emitting elements 130 are independently set without etching, thereby avoiding a series of problems such as etching residue and etching oxidation caused by etching to the anode auxiliary electrode 134. Importantly, the plurality of partition structures 141 are configured to process the anode auxiliary electrode 134 and the subsequent light-emitting functional layer 132 under the same ambient condition. After the anode auxiliary electrode 134 is formed, the light-emitting functional layer 132 is directly deposited without etching process, thereby avoiding the influence of the intermediate process on the film interface between the anode auxiliary electrode 134 and the light-emitting functional layer 132. Moreover, under the same ambient conditions, such as a vacuum ambient condition, the anode auxiliary electrode 134 and the light-emitting functional layer 132 are sequentially formed, so that the contact interface between the materials of the anode auxiliary electrode 134 and the light-emitting functional layer 132 is formed, thereby improving the luminous efficiency and service life of the plurality of light-emitting elements 130.

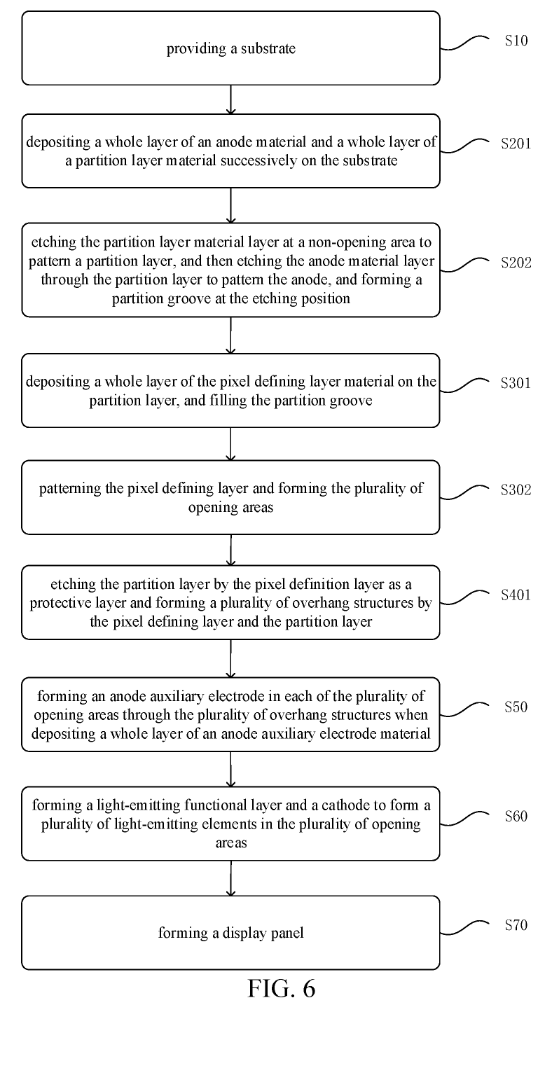

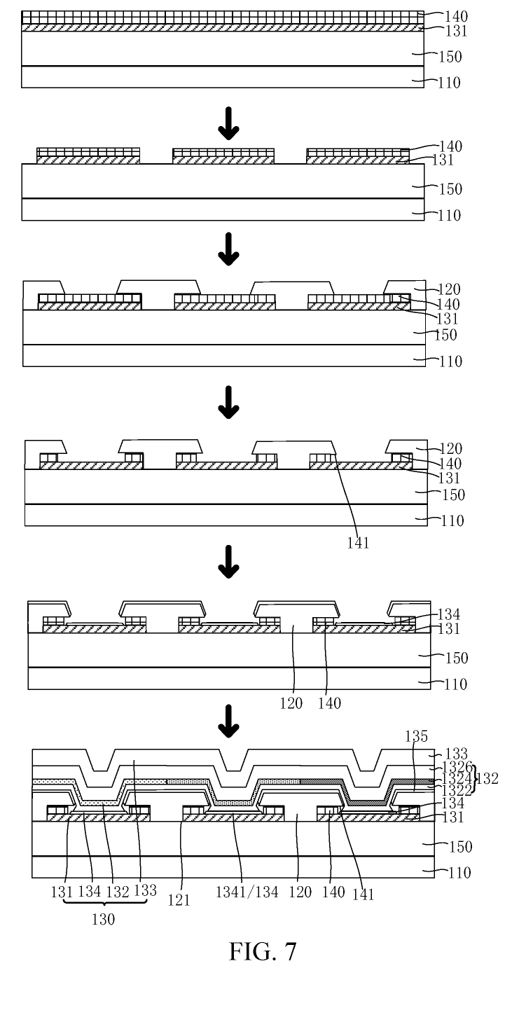

FIG. 6 is a schematic diagram of steps of another method for manufacturing a display panel according to the first embodiment of the present disclosure. FIG. 7 is a schematic diagram of manufacturing a display panel according to a first embodiment of the present disclosure. As shown in FIGS. 6 and 7, the step S10 also includes forming other structures such as a pixel driving layer on the substrate.

Specifically, the step S20 also includes:

S201: depositing an entire surface of an anode material layer and an entire surface of a partition layer material layer successively on the substrate;

S202: etching the partition layer material layer at a non-opening area to pattern a partition layer, and then etching the anode material layer through the partition layer to pattern the anode, and forming a partition groove at etched positions.

In some embodiments, the material of the anode 131 includes the aforementioned ITO, Ag, and ITO. The first transparent electrode layer 1311, the first reflective electrode layer 1312, and the second transparent conductive layer are respectively formed from these three materials. The first transparent electrode layer 1311, the first reflective electrode layer 1312, and the second transparent conductive layer need to be deposited in sequence, and then the partition layer 140 is deposited. During the etching process, the partition layer 140, the second transparent conductive layer, the first reflective electrode layer 1312, and the first transparent conductive layer are etched in sequence.

Specifically, the step of S30 includes:

S301: depositing an entire surface of the pixel-defining layer material on the partition layer, and filling the partition groove;

S302: patterning the pixel-defining layer and forming the plurality of opening areas, wherein a radial width of the pixel-defining layer is greater than that of the partition groove.

The step of S40 includes:

S401: etching the partition layer by the pixel-defining layer as a protective layer and forming a plurality of partition structures by the pixel-defining layer and the partition layer.

In some embodiments, in an orthographic projection on the substrate, a projection boundary of the partition layer is within a projection range of the pixel-defining layer, a preset distance is provided between an outermost projection boundary of the partition layer and an outermost projection boundary of the pixel-defining layer.

In step S50, the anode auxiliary electrode 134 is formed, and the first auxiliary electrode layer 1341 is formed with the material of the first auxiliary electrode layer 1341 to serve as the anode auxiliary electrode 134.

Of course, the light-emitting functional layer 132 may also be formed by metal mask evaporation technology instead of employing the plurality of partition structures 141 with mask-less evaporation technology. It is worth mentioning that in the metal mask evaporation technology, etching is also not required, and the evaporation environment is a vacuum environment, which may be consistent with the environment of the anode auxiliary electrode 134 utilizing mask-less evaporation technology, thereby achieving the above effect.

In some embodiments, the anode 131 is a three-layer structure of the first transparent electrode layer 1311, the first reflective electrode layer 1312 and the second transparent electrode layer 1313 in the above-mentioned first embodiment. However, in order to protect the first reflective electrode layer 1312 in the middle, the first transparent electrode layer 1311 and the second transparent electrode layer 1313 are sandwiched on both sides of the first reflective electrode layer 1312. When the partition groove 121 is etched in the three-layer anode 131 and the pixel-defining layer 120 is configured to insulate the anode 131, the three-layer anode 131 is not easy to etch, and it is easy to have problems of over-etching or incomplete etching.

Therefore, in addition to forming the anode auxiliary electrode 134 by utilizing the plurality of partition structures 141, the present disclosure also makes further improvements to the anode 131 on the basis of providing the anode auxiliary electrode 134.

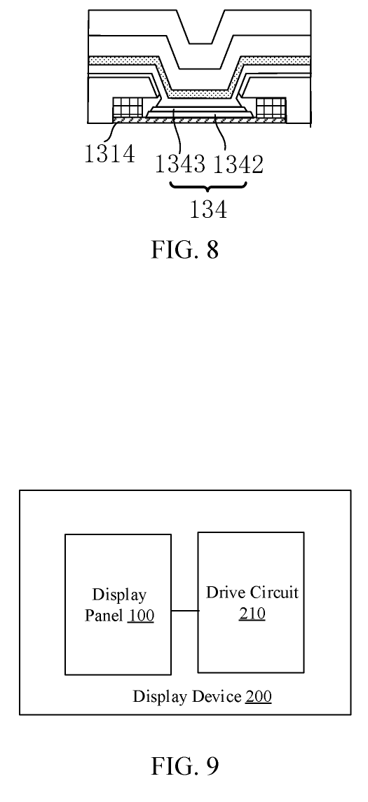

FIG. 8 is a schematic diagram of a display panel of a second embodiment of the present disclosure. As shown in FIG. 5, the other structures of the present disclosure are basically the same as those in the first embodiment, and the main difference lies in the anode 131, which includes a first electrode 1314, and the first electrode 1314 is formed of one or more of metal, metal alloy or metal oxide; the anode auxiliary electrode 134 includes a second reflective electrode layer 1342, and the second reflective electrode layer 1342 is formed of silver material or silver alloy material, and the second reflective electrode layer 1342 is arranged on the anode 131 and directly contacts the anode 131.

In some embodiments, the anode 131 is provided with only one electrode layer, namely, the first electrode 1314. The anode 131 may be formed of one or more of metal, metal alloy or metal oxide, so that the etching of the anode 131 is easier during the process of patterning the anode 131. The second reflective electrode layer 1342 is disposed in the anode auxiliary electrode 134, so that the reflective metal layer of the anode 131 may be formed by mask-less evaporation technology. That is, the plurality of partition structures 141 are employed to form the reflective metal layer in a vacuum environment in the same environment as the light-emitting functional layer 132. The process of the reflective metal layer no longer requires an etching step. In addition to the advantages mentioned above, the film quality of the reflective metal layer, namely, the second reflective electrode layer 1342, may be improved.

Specifically, in order to ensure the reflection quality of the second reflective electrode layer 1342, the thickness of the second reflective electrode layer 1342 is greater than or equal to 1,000 angstroms. Considering that the second reflective electrode layer 1342 generally needs to be formed of reflective metal, such as one or both of a magnesium material and silver material, and considering the isolation capability of the plurality of partition structures 141, the thickness of the second reflective electrode layer 1342 needs to be less than or equal to 5,000 angstroms. In combination with actual conditions, the second reflective electrode layer 1342 may have a suitable thickness in the range of 1500 angstroms to 3,000 angstroms.

Specifically, the anode auxiliary electrode 134 further includes a second auxiliary electrode layer 1343, the second auxiliary electrode layer 1343 is formed of metal oxides, and the second auxiliary electrode layer 1343 is disposed on the second reflective electrode layer 1342 and is in direct contact with the second reflective electrode layer 1342.

In some embodiments, the second auxiliary electrode layer 1343 may be formed of a transparent conductive material, such as ITO or IZO material. The anode 131 and the anode auxiliary electrode 134 serve as driving electrodes on one side of the plurality of light-emitting elements 130. The three-layer structure of ITO/IZO, Ag/Mg, and ITO/IZO formed by the combination of the anode 131 and the anode auxiliary electrode 134 has a good driving ability for the light-emitting functional layer 132.

In another embodiment, the second auxiliary electrode layer 1343 may be formed of silver oxide or magnesium oxide. The material of the second auxiliary electrode layer 1343 mainly depends on the material of the second reflective electrode layer 1342.

The second auxiliary electrode layer 1343 is formed by plasma-treating a surface of the first reflective electrode layer 1312 away from the substrate 110 to form a metal oxide film layer as the second auxiliary electrode layer 1343. When the second reflective electrode layer 1342 is a silver electrode, the second auxiliary electrode layer 1343 is a silver oxide electrode. When the second reflective electrode layer 1342 is a magnesium electrode, the second auxiliary electrode layer 1343 is a magnesium oxide electrode.

In some embodiments, after the second reflective electrode layer 1342 is vacuum-deposited, the surface of the second reflective electrode layer 1342 close to the cathode 133 may be oxidized by plasma treatment, thereby forming a thinner metal oxide layer on one side, and the metal oxide layer serves as the second auxiliary electrode layer 1343. Taking silver material as an example, the second reflective electrode is a silver electrode, and the second auxiliary electrode layer 1343 is silver oxide (Ag₂O). The work function of the silver oxide rises to 4.8eV to 5.1eV, which may better match the HOMO (5eV to 6eV) of the organic material in the light-emitting functional layer 132. In this way, the film interface performance between the anode 131 and the light-emitting functional layer 132 is improved while reducing the difficulty of the anode 131 process, thereby improving the efficiency and service life of the plurality of light-emitting elements 130.

In some embodiments, the process sequence in some embodiments is basically the same as that in the previous embodiment, and the difference lies in the employment of materials for the anode 131 and the anode auxiliary electrode 134. When the material of the second auxiliary electrode layer 1343 is an oxide of the material of the second reflective electrode layer 1342, the following steps are further included: after the process of the second reflective electrode layer 1342 in the anode auxiliary electrode 134 is completed, the surface of the second reflective electrode layer 1342 in the plurality of opening areas 101 is subjected to plasma treatment, so that the surface of the second reflective electrode layer 1342 is oxidized to form a metal oxide as the second auxiliary electrode layer 1343.

FIG. 9 is a schematic diagram of a display device according to the present disclosure. As shown in FIG. 9, the present disclosure further discloses a display device. The display device 200 includes a driving circuit 210 and any one of the display panels 100 in the above-mentioned embodiments 1 and 2. The driving circuit is configured to drive the display panel 100 to display.

It should be noted that the inventive concept of the present disclosure may be formed into many embodiments, but limitations of the application document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising:
a substrate;
a pixel-defining layer, disposed on the substrate and provided with a plurality of opening areas; and
a plurality of light-emitting elements, arranged in an array on the substrate and respectively located in the plurality of opening areas;
wherein each of the plurality of light-emitting elements comprises an anode, a light-emitting functional layer and a cathode, the anode is disposed on the substrate, the light-emitting functional layer is disposed on the anode, and the cathode is disposed on the light-emitting functional layer;
each of the plurality of light-emitting elements further comprises an anode auxiliary electrode, the anode auxiliary electrode is disposed between the anode and the light-emitting functional layer, the anode auxiliary electrode is formed of one or more of metal, metal alloy, or metal oxide; and
the display panel further comprises a plurality of partition structures, each of the plurality of partition structures is configured to separate the anode auxiliary electrodes of two adjacent light-emitting elements when depositing an entire surface of the anode auxiliary electrodes.

2. The display panel according to claim 1, wherein the anode comprises a first transparent electrode layer, a first reflective electrode layer, and a second transparent electrode layer, the first reflective electrode layer is disposed between the first transparent electrode layer and the second transparent electrode layer; the first reflective electrode layer is formed of reflective metal material;
the anode auxiliary electrode comprises a first auxiliary electrode layer, the first auxiliary electrode layer is disposed on the second transparent electrode layer and is in direct contact with the second transparent electrode layer; and
a thickness of the first auxiliary electrode layer is greater than or equal to 10 angstroms and less than or equal to 300 angstroms.

3. The display panel according to claim 1, wherein the display panel further comprises a partition layer, the partition layer is disposed below the pixel-defining layer and disposed on the anode, and the partition layer is in direct contact with the anode; and
in an orthographic projection on the substrate, a projection boundary of the partition layer is within a projection range of the pixel-defining layer, a preset distance is provided between an outermost projection boundary of the partition layer and an outermost projection boundary of the pixel-defining layer, each of the plurality of partition structures is formed by the pixel-defining layer and the partition layer.

4. The display panel according to claim 3, wherein the partition layer is formed of metal or metal alloy materials, and the partition layer is formed of different materials from the anode.

5. The display panel according to claim 3, wherein the preset distance is greater than or equal to 5,000 angstroms and less than or equal to 50,000 angstroms, and the thickness of the partition layer is greater than or equal to 100 angstroms and less than or equal to 10,000 angstroms.

6. The display panel according to claim 1, wherein the anode comprises a first electrode layer, and the first electrode layer is formed of one or more of metal, metal alloy, or metal oxide;
the anode auxiliary electrode comprises a second reflective electrode layer, the second reflective electrode layer is formed of silver material or silver-alloy material, and the second reflective electrode layer is disposed on the anode and is in direct contact with the anode; and
a thickness of the second reflective electrode layer is from 1,000 angstroms to 5,000 angstroms.

7. The display panel according to claim 6, wherein the anode auxiliary electrode further comprises a second auxiliary electrode layer, the second auxiliary electrode layer is formed of metal oxides, and the second auxiliary electrode layer is disposed on the second reflective electrode layer and is in direct contact with the second reflective electrode layer.

8. The display panel according to claim 7, wherein the metal oxide comprises indium tin oxide or indium zinc oxide.

9. The display panel according to claim 7, wherein the metal oxide comprises silver oxide or magnesium oxide.

10. The display panel according to claim 7, wherein the second auxiliary electrode layer is formed by plasma-treating a surface of the first reflective electrode layer away from the substrate to form a metal oxide film layer as the second auxiliary electrode layer.

11. The display panel according to claim 10, wherein the second auxiliary electrode layer is a silver oxide electrode when the second reflective electrode layer is a silver electrode, the second auxiliary electrode layer is a magnesium oxide electrode when the second reflective electrode layer is a magnesium electrode.

12. The display panel according to claim 6, wherein the display panel further comprises a partition layer, the partition layer is disposed below the pixel-defining layer and disposed on the anode, and the partition layer is in direct contact with the anode; and
in an orthographic projection on the substrate, a projection boundary of the partition layer is within a projection range of the pixel-defining layer, a preset distance is provided between an outermost projection boundary of the partition layer and an outermost projection boundary of the pixel-defining layer, each of the plurality of partition structures is formed by the pixel-defining layer and the partition layer.

13. The display panel according to claim 12, wherein the partition layer is formed of metal or metal alloy materials, and the partition layer is formed of different materials from the anode.

14. The display panel according to claim 12, wherein the preset distance is greater than or equal to 5,000 angstroms and less than or equal to 50,000 angstroms, and the thickness of the partition layer is greater than or equal to 100 angstroms and less than or equal to 10,000 angstroms.

15. A method for manufacturing a display panel, comprising:
providing a substrate;
forming an anode by depositing and patterning on the substrate;
forming a pixel-defining layer by depositing and patterning, and forming a plurality of opening areas;
forming a plurality of partition structures;
forming an anode auxiliary electrode in each of the plurality of opening areas through the plurality of partition structures when depositing an entire surface of an anode auxiliary electrode material;
forming a light-emitting functional layer and a cathode to form a plurality of light-emitting elements in the plurality of opening areas; and
forming a display panel.

16. The method for manufacturing a display panel according to claim 15, wherein the forming the anode by depositing and patterning on the substrate comprises:
depositing an entire surface of an anode material layer and an entire surface of a partition layer material layer successively on the substrate;
etching the partition layer material layer at a non-opening area to pattern a partition layer, and then etching the anode material layer through the partition layer to pattern the anode, and forming a partition groove at etched positions;
the forming a pixel-defining layer by depositing and patterning, and forming a plurality of opening areas comprises:
depositing an entire surface of the pixel-defining layer material on the partition layer, and filling the partition groove;
patterning the pixel-defining layer and forming the plurality of opening areas, wherein a radial width of the pixel-defining layer is greater than that of the partition groove;
the forming a plurality of partition structures comprises:
etching the partition layer by the pixel-defining layer as a protective layer and forming a plurality of partition structures by the pixel-defining layer and the partition layer;
wherein in an orthographic projection on the substrate, a projection boundary of the partition layer is within a projection range of the pixel-defining layer, a preset distance is provided between an outermost projection boundary of the partition layer and an outermost projection boundary of the pixel-defining layer.

17. The method for manufacturing a display panel according to claim 16, wherein the anode auxiliary electrode is formed of one or more of metal, metal alloy, or metal oxide;
the anode auxiliary electrode comprises a second reflective electrode layer and a second auxiliary electrode layer, the second reflective electrode layer is formed of silver material or silver-alloy material, the second reflective electrode layer is disposed on the anode and is in direct contact with the anode, the second auxiliary electrode layer is formed of metal oxides, and the second auxiliary electrode layer is disposed on the second reflective electrode layer and is in direct contact with the second reflective electrode layer.

18. The method for manufacturing a display panel according to claim 16, wherein a metal-oxide film layer is formed as the second auxiliary electrode layer by subjecting the surface of the first reflective electrode layer to plasma treatment on the side away from the substrate; and
a thickness of the second reflective electrode layer is from 1,000 angstroms to 5,000 angstroms.

19. A display device, comprising a display panel and a driving circuit configured to drive the display panel; wherein the display panel comprises:
a substrate;
a pixel-defining layer, disposed on the substrate and provided with a plurality of opening areas; and
a plurality of light-emitting elements, arranged in an array on the substrate and respectively located in the plurality of opening areas;
wherein each of the plurality of light-emitting elements comprises an anode, a light-emitting functional layer and a cathode, the anode is disposed on the substrate, the light-emitting functional layer is disposed on the anode, and the cathode is disposed on the light-emitting functional layer;
each of the plurality of light-emitting elements further comprises an anode auxiliary electrode, the anode auxiliary electrode is disposed between the anode and the light-emitting functional layer, the anode auxiliary electrode is formed of one or more of metal, metal alloy, or metal oxide; and
the display panel further comprises a plurality of partition structures, each of the plurality of partition structures is configured to separate the anode auxiliary electrodes of two adjacent light-emitting elements when depositing an entire surface of the anode auxiliary electrodes.
